(19) United States
(12) Patent Application Publication
(10) Pub. No.: US 2024/0353541 A1
(43) Pub. Date: Oct. 24, 2024

(54) LIDAR MEASURING METHOD AND DEVICE WITH SUB-PULSES PRODUCED BY BIREFRINGENCE IN THE LASER RESONATOR

(71) Applicant: ams-OSRAM International GmbH, Regensburg (DE)

(72) Inventor: Jens EBBECKE, Rohr In Niederbayern (DE)

(21) Appl. No.: 18/682,121

(22) PCT Filed: Jul. 29, 2022
(86) PCT No.: PCT/EP2022/071318

§ 371 Date: Feb. 8, 2024

(30) Foreign Application Priority Data
Aug. 13, 2021 (DE) 10 2021 121 096.8

(51) Int. Cl. G01S 7/4865; G01S 17/10

(52) U.S. Cl. CPC G01S 7/4865; G01S 17/10

(57) ABSTRACT

A measurement method includes emitting a transmission signal comprising at least one light pulse, wherein an amplitude of an intensity of the light pulse is modulated with a modulation frequency, detecting a receiving signal comprising at least a part of the transmission signal that is reflected from an external object, selecting at least one frequency component of the receiving signal corresponding to the modulation frequency of the transmission signal, and determining a distance to the external object from a time difference between the emission of the transmission signal and the detection of the selected frequency component of the receiving signal.

### CROSS-REFERENCE TO RELATED APPLICATIONS

The present application is a U.S. National Stage Application of International Application PCT/EP2022/071318, filed Jul. 29, 2022, and claims the priority of the German patent application DE 10 2021 121 096.8, filed Aug. 13, 2021; the entire disclosures of the above-listed applications are hereby explicitly incorporated by reference.

### FIELD

Various embodiments of the present disclosure relate to a measurement method and a measurement device.

### SUMMARY

Various embodiments of the present disclosure relate to an improved measurement method and an improved measurement device, which are configured to determine at least a distance to an external object by a time-of-flight measurement. In particular, in various embodiments, an improved distance resolution should be enabled.

According to one embodiment of the measurement method, a transmission signal comprising at least one light pulse is emitted. The light pulse has a certain duration. An intensity of the light of the light pulse is different from zero only during the duration of the light pulse. In particular, the light pulse is not a continuous light signal. For example, the light pulse has a duration that may range from 1 nanosecond to 100 nanoseconds, inclusive. An amplitude of the intensity of the light pulse is modulated, for example, with a sinusoidal signal with a modulation frequency that may range from 100 MHz to 1 GHz. The transmission signal can also comprise several light pulses. The following features of one light pulse may apply to all light pulses. It is also possible that these features differ for different light pulses. For example, different light pulses can have different durations.

The light pulse is emitted by a transmitter comprising a light source that is configured to emit light pulses during operation. For example, the light source comprises at least one laser diode or at least one light-emitting diode or is formed from a laser diode or a light-emitting diode.

A light pulse of the transmission signal may comprise coherent light or is formed from coherent light. Alternatively, a light pulse of incoherent light is also possible. A light pulse comprises, for example, light from the infrared to ultraviolet spectral range. A light pulse may comprise infrared light, for example with a wavelength that may range from 800 nanometers to 1800 nanometers, inclusive.

According to a further embodiment of the measurement method, an amplitude of an intensity of the light pulse is modulated with a modulation frequency. In particular, the intensity of the light pulse has a temporally periodic variation. For example, the intensity of the light pulse oscillates sinusoidally with the modulation frequency as a function of time. The amplitude of the temporally varying intensity of the modulated light pulse may range from 20% to 100%, inclusive, of a time-averaged intensity of the light pulse.

According to a further embodiment of the measurement method, a receiving signal is detected which comprises at least a part of the transmission signal reflected by an external object.

The receiving signal is detected, for example, by a photodetector, which converts the receiving signal into an electrical signal. The photodetector comprises, for example, at least one photodiode and/or at least one phototransistor or consists of a photodiode and/or a phototransistor. The photodetector may be located in the immediate vicinity of the light source of the transmitter. A distance between the photodetector and the light source may be much smaller than a distance between the photodetector and the external object. For example, the distance between the photodetector and the external object is at least by a factor of ten larger than the distance between the photodetector and the light source of the transmitter.

The photodetector may not receive direct light from the light source of the transmitter. In particular, the photodetector can be configured to detect the transmission signal that is at least partially reflected by the external object during operation.

The photodetector can be configured to determine the direction of a light beam incident on the photodetector. For example, the photodetector comprises a matrix-shaped arrangement of a plurality of photodiodes or phototransistors and an upstream imaging optics. In particular, the direction of the transmission signal that is reflected by the external object can thus be determined.

The receiving signal comprises a time interval which immediately follows a time of emission of the transmission signal. A duration of the time interval of the receiving signal comprises at least the sum of a propagation time of the transmission signal from the light source of the transmitter to the external object and a propagation time of the at least partially reflected transmission signal from the external object to the photodetector. In other words, the time interval of the receiving signal comprises at least the time of emission of the transmission signal and a time of detection of the at least partially reflected transmission signal from the external object.

In addition to the reflected transmission signal, the photodetector also receives background light, for example sunlight and/or light from artificial ambient lighting. The background light usually leads to background noise in the receiving signal. The background noise generally reduces the distance resolution of measurement methods for distance measurement, which are based, for example, on a time-of-flight measurement of the transmission signal. In particular, the intensity of the light pulse of the at least partially reflected transmission signal, which is detected by the photodetector, decreases with increasing distance between the photodetector and the external object. If the reflected transmission signal is too weak compared to the background noise, the at least partially reflected transmission signal can no longer be clearly identified from the background noise. The light propagation time can then no longer be determined accurately.

According to a further embodiment of the measurement method, at least one frequency component of the receiving signal that corresponds to the modulation frequency of the transmission signal is selected. The selected frequency component can, for example, be filtered from the receiving signal by a spectral analysis of the receiving signal.

By selecting a frequency component that corresponds to the modulation frequency of the transmission signal, the at least partially reflected transmission signal is filtered out of the receiving signal. In particular, this suppresses the background noise in the receiving signal and increases the signal-to-noise ratio. Thus, the distance resolution of measurement methods for distance measurement based on time-of-flight measurement can be increased.

According to a further embodiment of the measurement method, a distance to the external object is determined from a time difference between the emission of the transmission signal and the detection of the selected frequency component of the receiving signal.

The distance between the light source of the transmitter and the photodetector can be much smaller than the distance to the external object. For example, the distance between the light source and the external object can be larger than the distance between the light source and the photodetector by a factor of more than ten. In this case, the distance to the external object is determined by the speed of light of the light pulse, for example the speed of light in the ambient air, multiplied by half the time difference between the transmission signal being emitted and the selected frequency component of the receiving signal being detected.

According to at least one embodiment, the measurement method comprises the following steps:
emitting a transmission signal comprising at least one light pulse, wherein an amplitude of an intensity of the light pulse is modulated with a modulation frequency,
detecting a receiving signal comprising at least a part of the transmission signal that is reflected from an external object,
selecting at least one frequency component of the receiving signal corresponding to the modulation frequency of the transmission signal,
determining a distance to the external object from a time difference between the emission of the transmission signal and the detection of the selected frequency component of the receiving signal.

These steps are can be carried out in the order specified above.

One idea of the measurement method described herein is to improve the distance resolution of measurement methods for distance measurement that are based on a time-of-flight measurement of light pulses. In particular, the intensity of the light from at least one light pulse of the transmission signal is modulated with a modulation frequency. This modulation frequency is filtered out of the receiving signal in order to increase the signal-to-noise ratio.

In Lidar systems (short for “light detection and ranging”) for distance measurement, the maximum laser power of the transmitter for a given duration of the light pulse is limited by specifications for eye safety. The maximum detectable distance to the external object is thus limited by the background noise of the photodetector, for example by background light. The background noise can be reduced, for example, by an optical filter in front of the photodetector. The optical filter at least partially blocks background light outside a wavelength range of the transmission signal. However, in particular laser diodes in transmitters of Lidar systems can exhibit wavelength fluctuations, for example due to temperature changes in the environment. For this reason, the bandwidth of the optical filter cannot be selected to be arbitrarily small. This means that the background noise can only be partially suppressed with optical filters.

The present application is based, inter alia, on the idea that the range resolution of Lidar systems can be increased by modulating the intensity of the light of a light pulse of the transmission signal with a predetermined modulation frequency. By selecting the corresponding frequency component of the receiving signal at the modulation frequency of the transmission signal, the signal-to-noise ratio is improved, in particular. Accordingly, at least partially reflected transmission signals with a weaker intensity, for example from more distant external objects, can also be detected above the background noise. In particular, an optical filter can be dispensed with.

According to a further embodiment of the measurement method, the amplitude of the intensity of the light pulse is modulated with a sinusoidal signal. Alternatively, the amplitude can also be modulated with a signal of a different shape, for example with a rectangular or sawtooth-shaped signal. Further, the intensity of the light pulse can be modulated with any periodic signal shape comprising a fixed time period.

According to a further embodiment of the measurement method, a light pulse of the transmission signal is generated by a superposition of two unmodulated sub-pulses with light of different frequency, wherein the modulation frequency corresponds to a frequency difference of the light of the two sub-pulses.

In particular, the difference in frequency of the light of the two unmodulated sub-pulses is much smaller than the frequency of the light of the unmodulated sub-pulses. For example, the frequency of the light of an unmodulated sub-pulse may range from 100 terahertz to 400 terahertz, inclusive, while the frequency difference of the light of the two unmodulated sub-pulses is, for example, range from 100 megahertz to 10 gigahertz, inclusive.

The superposition of the two unmodulated sub-pulses with light of different frequencies thus leads to a beating. The intensity of the light pulse, which is generated by superimposing the two unmodulated sub-pulses, oscillates sinusoidally with the modulation frequency, which corresponds to the frequency difference of the light of the two sub-pulses. Here, the intensity of the modulated light pulse oscillates with an amplitude that corresponds to the time-averaged intensity of the light pulse.

The polarization of the light of the two unmodulated sub-pulses can be arbitrary. For example, both sub-pulses can comprise linearly polarized light, whereby the linear polarizations of the two unmodulated sub-pulses can in particular also be orthogonal to each other.

According to a further embodiment of the measurement method, the modulation frequency may range from 100 megahertz to 10 gigahertz, inclusive. For example, the intensity of the light pulse oscillates sinusoidally with a modulation frequency of approximately one gigahertz. The amplitude of the temporally oscillating intensity of the light pulse may range, for example, from 20% to 100%, inclusive, of the time-averaged intensity of the light pulse.

According to a further embodiment of the measurement method, the duration of a light pulse is at least ten times the inverse modulation frequency. In other words, the duration of the light pulse corresponds to at least ten times the period of the signal with which the amplitude of the intensity of the light pulse is modulated.

In particular, the modulation frequency with which the intensity of the light pulse is modulated has an uncertainty that is proportional to the inverse duration of the light pulse. In other words, the longer the duration of the light pulse, the more accurately the modulation frequency of the light pulse can be determined. In order to filter the modulation frequency of the light pulse as accurately as possible from the receiving signal and thus suppress the background noise in the best possible way, it is therefore advantageous for the duration of a light pulse to be as long as possible.

On the other hand, a duration of the light pulse that is as short as possible is advantageous, as the intensity of the light pulse can be increased for a shorter light pulse without jeopardizing eye safety. A higher intensity leads to a better signal-to-noise ratio and thus to a greater distance resolution. However, the minimum duration of a light pulse and the maximum intensity of the light pulse may be limited by technical restrictions of the light source.

In order to meet these conflicting demands on the duration of the light pulse, a duration of the light pulse may range from one nanosecond to 100 nanoseconds, for example.

According to a further embodiment of the measurement method, the selection of a frequency component of the receiving signal comprises a Fourier transform. For example, a fast Fourier transform can be used to spectrally analyze the receiving signal. Alternatively, it is also possible to use a narrowband bandpass filter to select a frequency component of the receiving signal corresponding to the modulation frequency of the transmission signal. For example, a lock-in amplifier can be used as a narrowband bandpass filter.

According to a further embodiment of the measurement method, a velocity of the external object is determined using a Doppler shift of the modulation frequency in the receiving signal. In particular, this allows to determine a velocity component of the external object in a radial direction. Here and in the following, radial refers to a direction parallel to a line between the photodetector and the external object. In particular, a movement of the external object in the radial direction leads to a Doppler shift in the modulation frequency of the reflected light pulse, which can be determined by spectral analysis of the receiving signal.

A measurement device is further specified. In particular, the measurement device is configured operate according to the measurement method described herein. This means that all features described for the measurement method that are relevant for the structure of the measurement device are also disclosed for the measurement device. Conversely, all features described for the measurement device that are relevant for the measurement method are also disclosed for the measurement method.

According to an embodiment of the measurement device, it comprises a transmission unit that emits a transmission signal comprising at least one light pulse during operation.

In particular, the transmission unit has a light source that is configured to generate light pulses during operation. For example, the light source comprises at least one laser diode or a light-emitting diode or consists of a laser diode or a light-emitting diode. The light source may emit light in the infrared spectral range, for example a wavelength may range from 800 nanometers to 1800 nanometers inclusive. A light pulse may have a duration ranging from one nanosecond to 100 nanoseconds, inclusive.

According to a further embodiment of the measurement device, an amplitude of an intensity of the at least one light pulse is modulated with a modulation frequency.

The intensity of the light pulse is modulated, for example, by operating the light source with a constant electric current during the duration of the light pulse and an additional, time-oscillating electric current during the duration of the light pulse. In particular, the constant electric current can be used to set an operating point of the light source, for example a laser diode. A frequency of the time-oscillating electric current determines the modulation frequency of the light pulse, while the amplitude of the time-oscillating intensity of the light pulse can be set by the ratio between the constant current and an amplitude of the time-oscillating current.

According to a further embodiment of the measurement device, the intensity of the light pulse is modulated by superimposing two unmodulated sub-pulses with light of different frequency. The superposition of the two unmodulated sub-pulses leads to a beating, whereby the intensity of the light pulse oscillates with a frequency difference between the light of the two sub-pulses. For example, the two unmodulated sub-pulses can be generated by two different light sources that emit light of different frequencies. Alternatively, the two unmodulated sub-pulses are generated by a single light source, which, in particular, provides two light modes with a fixed frequency difference.

According to a further embodiment of the measurement device, it comprises a receiving unit that detects a receiving signal during operation, the receiving signal comprising at least a part of the transmission signal reflected from an external object.

In particular, the receiving unit comprises at least one photodetector or consists of a photodetector that is configured to detect the transmission signal that is at least partially reflected by the external object during operation. The photodetector comprises, for example, a photodiode or a phototransistor. It is also possible that the photodetector comprises a plurality of photodiodes or phototransistors in a matrix-shaped arrangement. Furthermore, the photodetector can comprise imaging optics. For example, the photodetector is configured to also determine the direction of an incident light beam.

The receiving signal is converted by the photodetector into an electrical signal, for example into a photocurrent.

According to a further embodiment of the measurement device, it comprises an evaluation unit that analyzes the receiving signal during operation, and that is configured to select at least one frequency component of the receiving signal at the modulation frequency of the transmission signal.

A frequency component can be selected, for example, by performing a spectral analysis of the receiving signal. In particular, the evaluation unit performs a Fourier transformation of the receiving signal, for example, a fast Fourier transformation. This requires a selection of a time interval of the receiving signal. In particular, the time interval comprises a time of transmission of the transmission signal and a time of detection of the transmission signal that is at least partially reflected by the external object.

A narrowband bandpass filter can also be used to select a frequency component of the receiving signal. For example, the bandpass filter comprises a lock-in amplifier.

According to a further embodiment of the measurement device, the evaluation unit determines a time-of-flight of the transmission signal between the emission of the transmission signal and the detection of the transmission signal that is at least partially reflected by the external object at the modulation frequency of the transmission signal. This is used to determine a distance to the external object.

If the distance to the external object is much larger than the distance between the light source of the transmission unit and the photodetector of the receiving unit, the distance to the external object is calculated from half of the time-of-flight multiplied by a speed of light of the light pulse, for example the speed of light in the ambient atmosphere.

According to a further embodiment of the measurement device, the at least one light pulse comprises laser light or is formed from laser light.

Laser light is generated by stimulated emission and, unlike electromagnetic radiation that is generated by spontaneous emission, generally has a very high coherence length, a very narrow spectral linewidth and/or a high degree of polarization.

In order to determine the modulation frequency of a light pulse as accurately as possible, random fluctuations in the modulation frequency should be as small as possible. In order to reduce random fluctuations in the modulation frequency of a light pulse, a frequency-stable light source is advantageous. In particular, the spectral linewidth of the light emitted by the light source during operation is smaller than the modulation frequency of the light pulse.

According to a further embodiment of the measurement device, a spectral linewidth of the laser light is smaller than one tenth of the modulation frequency.

To improve the signal-to-noise ratio, it is advantageous to determine the modulation frequency as accurately as possible. Random fluctuations in the frequency of the laser light can lead to random shifts in the modulation frequency. Random fluctuations in the frequency of the laser light can therefore reduce the distance resolution of the measurement device. The spectral linewidth of the laser light may be less than one tenth of the modulation frequency. For example, the spectral linewidth of the laser light can be less than one hundredth of the modulation frequency.

According to a further embodiment of the measurement device, it comprises a resonator in which a laser medium and a birefringent optical element are arranged.

The resonator and the laser medium are configured to generate a population inversion in the laser medium during operation. Due to the population inversion, the electromagnetic radiation is generated in the laser medium by stimulated emission, which leads to the formation of electromagnetic laser radiation. Due to the generation of the electromagnetic laser radiation by stimulated emission, the electromagnetic laser radiation generally has a very high coherence length, a very narrow spectral linewidth and/or a high degree of polarization, in contrast to electromagnetic radiation generated by spontaneous emission.

The resonator comprises, for example, two opposing mirrors, with at least one mirror being at least partially transparent to the laser light in order to couple laser light generated during operation out of the resonator. The mirrors can be designed as external mirrors or as edge surfaces of the laser medium. The mirrors have, for example, a metallic layer that is highly reflective for laser light generated during operation. For example, the reflectivity of the mirrors may range from 99% to 99.9% for laser light generated during operation. The mirrors can also comprise or can be formed from a dielectric layer sequence configured to Bragg reflect the laser light generated during operation.

The laser medium comprises, for example, a semiconductor layer sequence with an active layer that is configured to generate the laser light. In particular, it is possible for an edge surface of the semiconductor layer sequence to form a mirror of the resonator. In this case, laser light is totally reflected at the transition between the semiconductor layer sequence and, for example, the ambient air. It is also possible that both mirrors of the resonator are formed by opposite edge surfaces of the semiconductor layer sequence.

For example, the birefringent optical element has an optical axis. Linearly polarized light is split into an ordinary and an extraordinary light beam in the birefringent optical element. The light of the ordinary light beam is polarized parallel to the optical axis and the light of the extraordinary light beam is polarized perpendicular to the optical axis. In particular, the birefringent optical element has two different refractive indices for the ordinary and extraordinary light beams. Accordingly, the propagation speeds of the ordinary and extraordinary light beams in the birefringent optical element are different. As a result, the optical length of the resonator is different for the ordinary light beam and the extraordinary light beam. Laser light that is coupled out of the resonator therefore has two orthogonal polarizations with different frequencies.

The superposition of the ordinary and extraordinary light beams outside the resonator leads to beating. The amplitude of the intensity of the laser light coupled out of the resonator is thus modulated, with the modulation frequency corresponding to the frequency difference between the ordinary and extraordinary light beam.

According to a further embodiment of the measurement device, the birefringent optical element comprises a material from the following group or is formed from a material from the following group: quartz, lithium niobate, lithium tantalate, magnesium fluoride.

According to a further embodiment of the measurement device, the birefringent optical element is an electro-optical element. In particular, the refractive indices of the birefringent optical element can be changed by applying an electric field. For example, the electro-optical element is a Pockels cell or a Kerr cell. Thus, by applying an electric field, the frequency difference between the ordinary and extraordinary light beams coupled out of the resonator can be adjusted.

According to a further embodiment of the measurement device, the laser medium comprises a semiconductor layer sequence with an active layer for generating the laser light.

For example, the semiconductor layer sequence comprises a III/V compound semiconductor material. A III/V compound semiconductor material comprises at least one element from the third main group, such as B, Al, Ga, In, and one element from the fifth main group, such as N, P, As. In particular, the term “III/V compound semiconductor material” comprises the group of binary, ternary or quaternary compounds which contain at least one element from the third main group and at least one element from the fifth main group, for example nitride and phosphide compound semiconductors. Such a binary, ternary or quaternary compound can also have, for example, one or more dopants and additional components.

In particular, the semiconductor layer sequence comprises an arsenide compound semiconductor material, whereby the semiconductor layer sequence or at least a part thereof, for example, at least the active layer, which can include AlₙGaₘIn₁₋ₙ₋ₘAs, where 0≤n≤1, 0≤m≤1 and n+m≤1. This material does not necessarily have to have a mathematically exact composition according to the above formula. Rather, it can have one or more dopants as well as additional components. For the sake of simplicity, however, the above formula only contains the essential components of the crystal lattice (Al or As, Ga, In), even if these may be partially replaced by small amounts of other substances.

According to a further embodiment of the measurement device, the active layer is periodically structured and forms an interference filter. The periodic structuring of the active layer leads to a wavelength-selective Bragg reflection of the light generated in the active layer. As a result, the spectral linewidth of the laser light generated during operation can be reduced.

Furthermore, the periodic structuring of the semiconductor layer sequence can also take place outside the active layer. In particular, the semiconductor layer sequence can comprise at least one dielectric Bragg mirror, which forms at least part of the resonator. Dielectric Bragg mirrors lead to a wavelength-selective reflection of the light generated in the active layer and can reduce the spectral linewidth of the semiconductor laser.

According to a further embodiment of the measurement device, the modulation frequency is adjusted by a thickness of the birefringent optical element and/or by an angle between an optical axis of the birefringent optical element and an optical axis of the resonator.

For example, the thickness of the birefringent optical element may range from 100 nanometers to 100 micrometers. A thicker birefringent optical element leads to a larger difference in the optical length of the resonator for the ordinary and extraordinary light beams. A thicker birefringent optical element can therefore increase the frequency difference between the ordinary and extraordinary light beams.

According to a further embodiment of the measurement device, the evaluation unit is configured to determine a Doppler shift of the modulation frequency of the receiving signal. In particular, the Doppler shift of the modulation frequency of the transmission signal that is at least partially reflected by the external object can be determined by a spectral analysis of the receiving signal. The Doppler shift is directly proportional to a radial velocity of the external object. In particular, by determining the Doppler shift, the radial speed of the external object can be determined by detecting a single light pulse.

Further advantageous embodiments and further developments of the measurement method and the measurement device are apparent from the exemplary embodiments described in conjunction with the figures in the following.

### BRIEF DESCRIPTION OF THE DRAWINGS

FIG. 1 shows a schematic flow diagram with steps of a measurement method according to an exemplary embodiment.

FIG. 2 shows a schematic light pulse of a measurement method according to an exemplary embodiment.

FIG. 3 shows a further schematic light pulse of a measurement method according to an exemplary embodiment.

FIG. 4 shows a frequency spectrum of a receiving signal of a measurement method according to an exemplary embodiment.

FIG. 5 shows a schematic structure of a measurement device according to an exemplary embodiment.

FIG. 6 shows a schematic structure of a transmission unit of a measurement device according to an exemplary embodiment.

FIG. 7 shows a schematic structure of a transmission unit of a measurement device according to a further exemplary embodiment.

Elements that are identical, similar, or have the same effect, are denoted by the same reference signs in the figures. The figures and the proportions of the elements shown in the figures are not to be regarded as true to scale. Rather, individual elements, in particular layer thicknesses, may be shown exaggeratedly large for better representability and/or better understanding.

### DETAILED DESCRIPTION

FIG. 1 shows a schematic flow diagram with steps of a measurement method according to an exemplary embodiment. In the first step 91 of the measurement method, a transmission signal 11 is emitted, which comprises at least one light pulse 12. In particular, the light pulse 12 may have a duration 121 ranging from one nanosecond to 100 nanoseconds, inclusive.

An intensity I of the light of the light pulse 12 is not constant in time during its duration 121. In particular, an amplitude 122 of the intensity I of the light pulse 12 is modulated at a modulation frequency 123. The modulation frequency 123 may range from 100 MHz to 10 GHz inclusive. This corresponds to a modulation period 124 from one tenth of a nanosecond to 10 nanoseconds. The amplitude 122 of the temporally sinusoidally 126 varying intensity I of the light pulse 12 may range from 20% and 100%, inclusive, of a time-averaged intensity 125 of the light pulse 12.

In a second step 92 of the measurement method, a receiving signal 21 is detected by a photodetector. The receiving signal 21 comprises at least a part of the transmission signal 11 that is at least partially reflected by an external object 4. Furthermore, the receiving signal 21 comprises background light, for example sunlight and/or light from artificial ambient lighting. The photodetector converts the receiving signal 21 into an electrical signal.

In a third step 93 of the measurement method, at least one frequency component 22 of the receiving signal 21 is selected which corresponds to the modulation frequency 123 of the transmission signal 11. As a result, the transmission signal 11 that is at least partially reflected from the external object 4 can be filtered from a background noise 23 of the photodetector due to background light. The frequency component 22 is selected by a fast Fourier transform of the receiving signal 21.

In a fourth step 94 of the measurement method, a distance 5 to the external object 4 is determined from a time-of-flight. The time-of-flight results from a time difference between the emission of the transmission signal 11 and the detection of the selected frequency component 22 of the receiving signal 21.

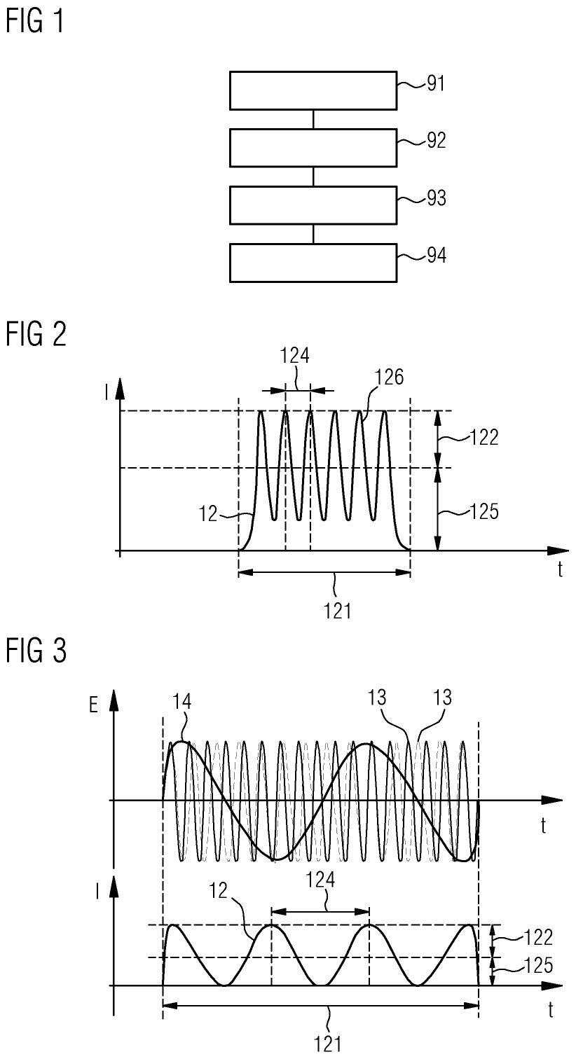

FIG. 2 schematically shows an intensity I of the light of a light pulse 12 as a function of time t according to an exemplary embodiment. The light pulse has a duration 121 during which the intensity I of the light pulse 12 is modulated with an amplitude 122 and a modulation period 124. The modulation period 124 is the inverse of a modulation frequency 123. The amplitude 122 is approximately 75% of a time-averaged intensity 125 of the light pulse. For ease of visualization, the duration of the light pulse in this example corresponds to approximately five modulation periods 124. However, the duration 121 of a light pulse 12 can be longer than ten modulation periods 124, thereby reducing an uncertainty of the modulation frequency 123, which is inversely proportional to the duration 121 of the light pulse 12. A low uncertainty of the modulation frequency 123 is advantageous in order to be able to better filter the transmission signal 12 that is at least partially reflected by the external object 4 from the background noise 23.

FIG. 3 schematically shows an electric field strength E and an intensity I of a light pulse 12 according to a further exemplary embodiment as a function of time t. The intensity I of the light of the light pulse 12 is proportional to the square of the electric field strength E. The light pulse 12 is created by the superposition of two unmodulated sub-pulses 13 with light of different frequency. This results in a beating 14, whereby the modulation frequency 123 of the intensity I of the light pulse 12 corresponds to a frequency difference of the light of the two unmodulated sub-pulses 13.

For better visualization, a frequency difference of the light of the two sub-pulses 13 is approximately one fifth of the frequency of the light of a sub-pulse 13. However, in the case of sub-pulses 13 of infrared light with a frequency of, for example, 100 terahertz and a frequency difference of, for example, one gigahertz, the frequency difference is only one hundred thousandth of the frequency of the light of a sub-pulse 13. The electric field strength E of the beating 14 and the intensity I of the light pulse 12 is therefore only shown as a time average over one oscillation period of the electric field strength E of the light of a sub-pulse 13. Due to the beating 14, an amplitude 122 corresponds to a time-averaged intensity 125 of the light pulse 12. For better visualization, a short pulse duration 121 is shown here analogous to FIG. 3 in comparison to the modulation period 124. The duration 121 of the light pulse can be larger than ten modulation periods 124.

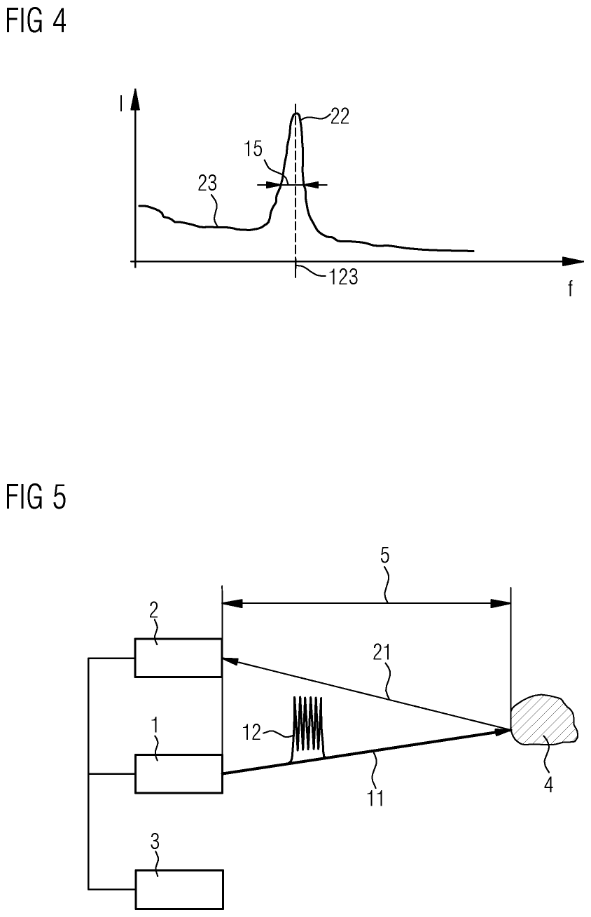

FIG. 4 shows a frequency spectrum of a receiving signal 21 according to an exemplary embodiment, which follows from a Fourier transform of a receiving signal 21. In particular, an intensity I of the receiving signal 21 is shown as a function of a frequency f. The intensity I of a transmission signal 11 that is at least partially reflected by an external object 4 is modulated with a modulation frequency 123 and is shown as a peak in the frequency spectrum above a background noise 23. In particular, a frequency component 22 corresponding to the peak of the frequency spectrum at the modulation frequency 123 is selected in the third step 93 of the measurement method.

The peak in the frequency spectrum has a spectral linewidth 15, which is composed in particular of an uncertainty of the modulation frequency 123 due to a finite duration 121 of a light pulse 12 and of a spectral linewidth 15 of the laser light of a light pulse 12. From a time difference between an emission of a light pulse 12 and a time at which the peak in the frequency spectrum occurs at the modulation frequency 123, a propagation time of the light pulse 12 and from this a distance 5 to the external object 4 can be determined.

A radial velocity of the external object 4 leads to a Doppler shift of the frequency at which the peak in the frequency spectrum occurs, which corresponds to the transmission signal 11 that is at least partially reflected by the external object 4. This Doppler shift can be used to determine the radial velocity of the external object 4.

FIG. 5 shows a schematic structure of a measurement device according to an exemplary embodiment, which comprises a transmission unit 1, a receiving unit 2 and an evaluation unit 3. The transmission unit 1 is configured to emit a transmission signal 11 during operation, which comprises at least one light pulse 12. The light pulse 12 comprises infrared laser light with a wavelength that may range from 800 nanometers to 1800 nanometers.

The receiving unit 2 has at least one photodetector, which is configured to detect a receiving signal 21. In particular, the photodetector is configured to detect the transmission signal 11 that is at least partially reflected by an external object 4.

A light source of the transmission unit 1 and the photodetector of the receiving unit 2 can be arranged directly next to each other. In particular, a distance between the light source of the transmission unit 1 and the photodetector of the receiving unit 2 is much smaller than a distance 5 to the external object 4. For example, the distance 5 to the external object 4 is at least ten times larger than the distance between the light source and the photodetector. The photodetector may not receive direct light from the transmission unit 1 but can be configured to receive indirect light from the transmission unit 1 that is reflected by an external object 4.

The photodetector of the receiving unit 2 converts the receiving signal 21 into an electrical signal, which is analyzed by the evaluation unit 3. In particular, the evaluation unit 3 is configured to select a frequency component 22 from the receiving signal 21 which corresponds to the modulation frequency of the transmission signal 11. As a result, the transmission signal 11 that is at least partially reflected by the external object 4 is filtered out of a background noise 23. The background noise 23 is caused, for example, by ambient light, which also impinges on the photodetector.

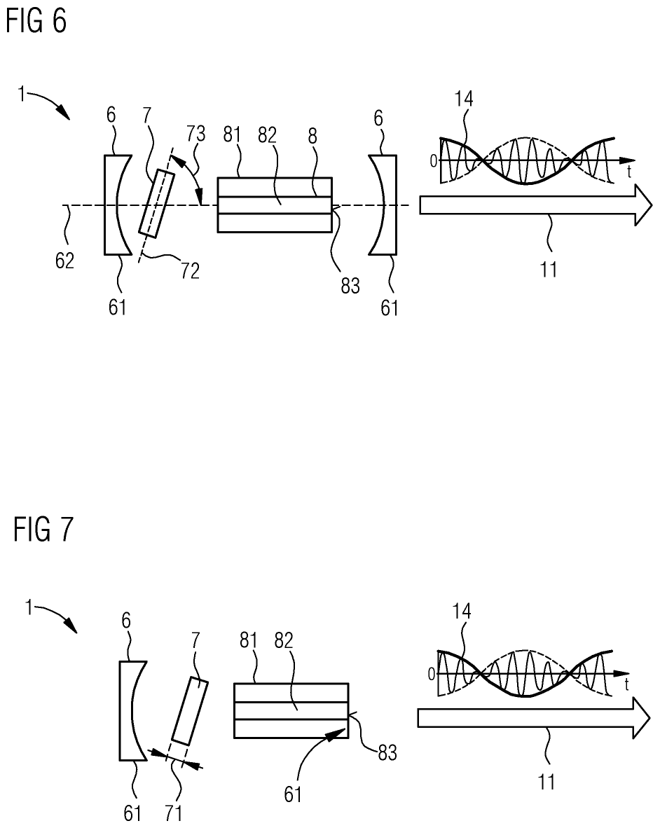

FIG. 6 shows a schematic structure of a transmission unit 1 of a measurement device according to an exemplary embodiment. The transmission unit 1 comprises a resonator 61 that includes two opposing external mirrors 6. At least one of the two external mirrors 6 is partially translucent and is configured to couple out the laser light generated during operation and thus the transmission signal 11. A birefringent optical element 7 and a semiconductor layer sequence 81 with an active layer 82 for generating laser light are arranged inside the resonator 61.

A population inversion is generated in the active layer 82 in conjunction with the resonator 61. Due to the population inversion, the electromagnetic radiation is generated in the active layer 82 by stimulated emission, which leads to the formation of electromagnetic laser radiation. Due to the generation of the electromagnetic laser radiation by stimulated emission, the electromagnetic laser radiation generally has a very high coherence length, a very narrow emission spectrum and/or a high degree of polarization, in contrast to electromagnetic radiation generated by spontaneous emission.

In this exemplary embodiment, the semiconductor layer sequence 81 is an edge-emitting semiconductor laser chip that emits light in the infrared wavelength range. Alternatively, a surface-emitting semiconductor laser chip can also be arranged in the resonator 61. In this exemplary embodiment, the edge surfaces 83 of the semiconductor layer sequence 81 are not configured to reflect the laser light generated during operation and, in particular, do not form a highly reflective resonator for laser light generated during operation.

The birefringent optical element 7 has an optical axis 72 and splits laser light in the resonator into an ordinary and an extraordinary light beam. Due to the different refractive indices for the ordinary and the extraordinary light beam in the birefringent optical element 7, an optical length of the resonator 61 is different for the ordinary and the extraordinary light beam. The laser light coupled out of the resonator 61 thus has a different frequency for the ordinary and the extraordinary light beam. The ordinary and extraordinary light beams are polarized perpendicular to each other and interfere with each other, in particular outside of the resonator. The ordinary and the extraordinary light beam can thus form two sub-pulses 13, the superposition of which leads to a beating 14 and thus to a modulation of the intensity of the light of a laser pulse 12. The modulation frequency 123 is determined by a frequency difference between the ordinary and the extraordinary light beam.

The modulation frequency can be adjusted by the thickness 71 of the birefringent optical element 7. Furthermore, the modulation frequency can be adjusted by an angle 73 between an optical axis 72 of the birefringent optical element 7 and an optical axis 62 of the resonator 61.

FIG. 7 shows a further exemplary embodiment of a transmission unit 1 of a measurement device comprising an optical resonator 61 in which a birefringent optical element 7 and a semiconductor layer sequence 81 are arranged. In contrast to the exemplary embodiment in FIG. 2, here an edge surface 83 of the semiconductor layer sequence 81 is formed as a mirror and thus as part of the optical resonator 61. In particular, the edge surface 83 has a reflectivity of more than 99% for laser light generated during operation and thus replaces one of the external mirrors 6 of the resonator 61 in the exemplary embodiment of FIG. 6.

The present disclosure is not limited to the exemplary embodiments by the description thereof. Rather, the present disclosure includes any new feature as well as any combination of features, which includes in particular any combination of features in the patent claims, even if this feature or combination itself is not explicitly stated in the patent claims or exemplary embodiments.

### LIST OF REFERENCE SIGNS

1 transmission unit
11 transmission signal
I intensity
t time
f frequency
12 light pulse
121 duration
122 amplitude
123 modulation frequency
124 modulation period
125 mean intensity
126 sinusoidal signal
13 sub-pulse
14 beating
15 spectral linewidth
2 receiving unit
21 receiving signal
22 frequency component
23 background noise
3 evaluation unit
4 external object
5 distance
6 mirror
61 resonator
62 optical axis
7 birefringent optical element
71 thickness
72 optical axis
73 angle
8 laser medium
81 semiconductor layer sequence
82 active layer
83 edge surface
91 first step
92 second step
93 third step
94 fourth step

1. A measurement method comprising:
emitting a transmission signal comprising at least one light pulse, wherein an amplitude of an intensity of the light pulse is modulated with a modulation frequency and the modulation frequency is between 500 MHz and 10 GHz, inclusive,
detecting a receiving signal comprising at least a part of the transmission signal that is reflected from an external object,
selecting at least one frequency component of the receiving signal corresponding to the modulation frequency of the transmission signal,
determining a distance to the external object from a time difference between the emission of the transmission signal and the detection of the selected frequency component of the receiving signal,
wherein one light pulse of the transmission signal is generated by a superposition of two unmodulated sub-pulses with light of different frequency, and
wherein the modulation frequency corresponds to a frequency difference of the light of the two sub-pulses.

2. The measurement method according to claim 1, wherein the amplitude of the intensity of the light pulse is modulated with a sinusoidal signal.

3. (canceled)

4. The measurement method according to claim 1, wherein a duration of the light pulse is at least ten times the inverse modulation frequency.

5. The measurement method according to claim 1, wherein the selection of a frequency component comprises a Fourier transform of the receiving signal.

6. The measurement method according to claim 1, wherein a velocity of the external object is determined using a Doppler shift of the modulation frequency in the receiving signal.

7. A measurement device, comprising:
a transmission unit configured to emit a transmission signal during operation, the transmission signal comprising at least one light pulse in which an amplitude of an intensity is modulated with a modulation frequency,
a receiving unit configured to detect a receiving signal during operation, the receiving signal comprising at least a part of the transmission signal reflected from an external object, and
an evaluation unit configured to analyze the receiving signal during operation, and that is configured to select at least one frequency component of the receiving signal at the modulation frequency and to determine at least a distance to the external object from a time-of-flight of the transmission signal determined therefrom, wherein
at least one light pulse comprises laser light, and
the transmission unit comprises a resonator in which a laser medium and a birefringent optical element are arranged.

8. The measurement device according to claim 7, wherein a spectral linewidth of the laser light is smaller than one tenth of the modulation frequency.

9. The measurement device according to claim 7, wherein the birefringent optical element comprises a material selected from the following group: Quartz, lithium niobate, lithium tantalate, magnesium fluoride.

10. The measurement device according to claim 7, wherein the birefringent optical element is an electro-optical element.

11. The measurement device according to claim 7, wherein the laser medium comprises a semiconductor layer sequence with an active layer for generating laser light, wherein the active layer is periodically structured and forms an interference filter.

12. The measurement device according to claim 7, wherein the modulation frequency is adjusted by a thickness of the birefringent optical element and/or by an angle between an optical axis of the birefringent optical element and an optical axis of the resonator.

13. The measurement device according to claim 7, wherein the evaluation unit is configured to determine a Doppler shift of the modulation frequency of the receiving signal.
